(19) United States
(12) Patent Application Publication
(10) Pub. No.: US 2024/0168131 A1
(43) Pub. Date: May 23, 2024

(54) OPTICAL DEVICE AND LIDAR DEVICE EACH INCLUDING HEATER COMBINED TEMPERATURE SENSOR

(71) Applicant: SAMSUNG ELECTRONICS CO., LTD., Suwon-si (KR)

(72) Inventors: Woosung KIM, Suwon-si (KR); Hyunil BYUN, Suwon-si (KR); Dongjae SHIN, Suwon-si (KR); Changbum LEE, Suwon-si (KR); Changgyun SHIN, Suwon-si (KR); Tatsuhiro OTSUKA, Suwon-si (KR)

(73) Assignee: SAMSUNG ELECTRONICS CO., LTD., Suwon-si (KR)

(21) Appl. No.: 18/376,657

(22) Filed: Oct. 4, 2023

(30) Foreign Application Priority Data
Nov. 21, 2022 (KR) 10-2022-0156791

(51) Int. Cl. G01S 7/481; G01R 19/25; G01S 17/931

(52) U.S. Cl. CPC G01S 7/4811; G01R 19/25; G01S 7/4814; G01S 17/931

(57) ABSTRACT

An optical device and a light detection and ranging (LiDAR) device each including a heater combined temperature sensor are disclosed. The optical device including the heater combined temperature sensor may include a heater, an analog-to-digital converter (ADC) configured to measure a voltage of the heater, a memory storing a measurement value, and a micro-controller configured to estimate a temperature of the heater based on relationship between the measurement value and the temperature.

### CROSS-REFERENCE TO RELATED APPLICATION

This application is based on and claims priority under 35 U.S.C. § 119 to Korean Patent Application No. 10-2022-0156791, filed on Nov. 21, 2022, in the Korean Intellectual Property Office, the disclosure of which is incorporated by reference herein in its entirety.

### BACKGROUND

### 1. Field

The disclosure relates to an optical device and a light detection and ranging (LiDAR) device each including a heater combined temperature sensor.

### 2. Description of the Related Art

Silicon photonics integrated circuits may enable the implementation of multiple optical devices on a single chip using a high degree of integration in a complementary metal-oxide-semiconductor (CMOS) manufacturing process. These silicon photonics integrated circuits may be highly utilized in the optical communication field or the optical sensor field.

However, the performance of silicon photonics integrated circuits tends to be highly dependent on a temperature range in which the silicon photonics integrated circuits operate. Accordingly, silicon photonics integrated circuits may be driven in accordance with temperature changes using various types of temperature sensors to monitor and adjust for temperature changes, and thereby to ensure optimal performance.

### SUMMARY

One or more example embodiments provide an optical device and a light detection and ranging (LiDAR) device each including a heater combined temperature sensor.

According to an aspect of the present disclosure, an optical device may include: a substrate; a waveguide disposed on the substrate; a heater configured as a silicon region doped on a part of the substrate; an analog-to-digital converter (ADC) configured to measure a voltage of the heater and convert the voltage of the heater into an ADC conversion value; a memory storing relation information between temperature and the ADC conversion value; and a micro-controller configured to estimate a temperature of the heater using the relation information between the temperature and the ADC conversion value.

A doped width of the heater may be equal to or greater than 1 μm and equal to or less than 3 μm, and a doped depth of the heater may be equal to or greater than 100 nm and equal to or less than 200 nm.

A doping concentration of the heater may be equal to or greater than 4.5 s 10¹⁹ cm⁻³ and equal to or less than 1.0 s 10²⁰ cm⁻³.

The heater may have one of a ring shape, a straight line shape, a race track shape, and an S-band shape.

The optical device may include: a digital-to-analog converter (DAC) configured to convert an adjustment signal according to the temperature calculated by the micro-controller into an adjustment voltage; and a driver configured to receive the adjustment voltage and supply current.

The micro-controller may be configured to calculate a relationship between the temperature and the ADC conversion value using temperature information obtained from a thermometer and the ADC conversion value.

According to another aspect of the present disclosure, a light detection and ranging (LiDAR) device may include: a tunable laser diode; a phase shifter; an optical amplifier; an antenna; a heater configured as a doped silicon region; and a heater combined temperature sensor.

The heater and the heater combined temperature sensor may be disposed inside the tunable laser diode.

The heater and the heater combined temperature sensor may be disposed adjacent to the phase shifter.

The heater and the heater combined temperature sensor may be disposed adjacent to the optical amplifier.

The heater and the heater combined temperature sensor may be disposed adjacent to the antenna.

A doped width of the heater may be equal to or greater than 1 μm and equal to or less than 3 μm, and a doped depth of the heater may be equal to or greater than 100 nm and equal to or less than 200 nm.

A doping concentration of the heater may be equal to or greater than 4.5 s 10¹⁹ cm⁻³ and equal to or less than 1.0 s 10²⁰ cm⁻³.

The heater may have one of a ring shape, a straight line shape, a race track shape, and an S-band shape.

The heater combined temperature sensor may include: an analog-to-digital converter (ADC) configured to measure a voltage of the heater and convert the voltage of the heater into an ADC conversion value; a memory storing relation information between temperature and the ADC conversion value; and a micro-controller configured to estimate a temperature using the relation information between the temperature and the ADC conversion value.

The heater combined temperature sensor may further include: a digital-to-analog converter (DAC) configured to convert an adjustment signal according to the temperature calculated by the micro-controller into an adjustment voltage; and a driver configured to receive the adjustment voltage and supply current.

The micro-controller may be configured to calculate a relationship between the temperature and the ADC conversion value using temperature information obtained from a thermometer and the ADC conversion value.

According to another aspect of the present disclosure, an optical device may include: a doped silicon thermistor configured to collect temperature sensing data; a waveguide coupled with the doped silicon thermistor; an analog digital converter (ADC) configured to convert an analog signal containing the temperature sensing data into a digital signal that represents a digital temperature value; a memory storing an ADC fitting function that expresses a relation between ADC conversion values and temperatures; and a processor configured to estimate a temperature of the doped silicon thermistor based on the digital temperature value and the ADC fitting function.

The optical device may be a light detection and ranging (LiDAR) sensor, and may further include: a tunable laser diode; a phase shifter; an optical amplifier; and an antenna.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating a heater combined temperature sensor according to an embodiment;

FIG. 2A is a graph showing a correlation between resistance and voltage of the heater 111 and temperature, and FIG. 2B is a graph showing a correlation between an analog-to-digital converter (ADC) conversion value and temperature;

FIG. 3 is a schematic diagram of a tunable laser diode (TLD) including a heater combined temperature sensor according to an embodiment;

FIG. 4 is a diagram schematically illustrating a ring structure of FIG. 3;

FIG. 5 is a cross-sectional view of the ring structure of FIG. 4 taken along a line I-I;

FIG. 6 is a schematic diagram of a TLD including a heater combined temperature sensor according to an embodiment;

FIG. 7 is a diagram schematically illustrating a ring structure of FIG. 6;

FIG. 8 is a cross-sectional view taken along a line II-II of FIG. 7;

FIG. 9 is a schematic diagram of an optical phased array (OPA) including a heater combined temperature sensor according to an embodiment;

FIGS. 10 to 11 are cross-sectional views taken along a line III-Ill of FIG. 9 according to an embodiment;

FIGS. 12 to 13 are cross-sectional views taken along the line III-Ill of FIG. 9 according to another embodiment;

FIG. 14 is a cross-sectional view taken along a line IV-IV of FIG. 9 according to an embodiment;

FIG. 15 is a cross-sectional view along the line IV-IV of FIG. 9 according to another embodiment;

FIG. 16 is a cross-sectional view taken along a line V-V of FIG. 9 according to an embodiment;

FIG. 17 is a cross-sectional view taken along the line V-V of FIG. 9 according to another embodiment;

FIGS. 18 to 20 are diagrams schematically illustrating a waveguide and a heater according to another embodiment;

FIGS. 21A and 21B are diagrams schematically illustrating a doping process of a heater according to an embodiment;

FIG. 22 is a block diagram schematically illustrating a beam steering apparatus according to an embodiment; and

FIG. 23 is a block diagram illustrating a LiDAR device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments of the disclosure will be described in detail with reference to the accompanying drawings. In the following drawings, the same reference numerals refer to the same components, and the size of each component in the drawings may be exaggerated for clarity and convenience of description. Meanwhile, the embodiments described below are merely exemplary, and various modifications are possible from these embodiments.

Hereinafter, what is referred to as “on” may include not only directly above, below, left and right in contact, but also above, below, left and right in non-contact. The singular expression includes the plural expression unless the context clearly dictates otherwise. Also, when a part “includes” a certain component, it means that other components may be further included, rather than excluding other components, unless otherwise stated.

The use of “the” and other demonstratives similar thereto may correspond to both a singular form and a plural form. Unless the order of operations of a method according to the disclosure is explicitly mentioned or described otherwise, the operations may be performed in a proper order. The disclosure is not limited to the order the operations are mentioned.

The term used in the embodiments such as “unit” or “module” indicates a unit for processing at least one function or operation, and may be implemented in hardware or software, or in a combination of hardware and software.

The connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language provided herein, is intended merely to better illuminate the disclosure and does not pose a limitation on the scope of the disclosure unless otherwise claimed.

One or more embodiments provide a silicon photonics integrated circuit including a heater combined temperature sensor according to an embodiment will be described. The silicon photonics integrated circuit according to the embodiments of the present disclosure may be used to implement various types of optical sensors (e.g., a light detection and ranging (LiDAR) sensor) and a communication module.

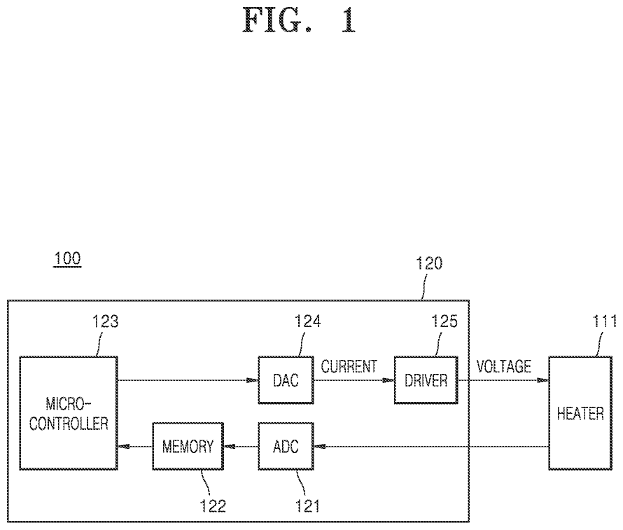

FIG. 1 is a block diagram illustrating a heater combined temperature sensor according to an embodiment.

Referring to FIG. 1, a heater combined temperature sensor 100 may include a heater 111 and a heater combined temperature sensor unit 120.

The heater 111 may configured as a doped silicon region. The resistance and temperature of the heater 111 may have a certain correlation because the resistance of the heater 111 may change as the temperature changes. A change in the resistance of the heater 111 may lead to a change in at least one of voltage or current. Accordingly, at least one of the voltage or current of the heater 111 may also have a certain correlation with the temperature change.

The heater 111 and the heater combined temperature sensor unit 120 may be included inside a light source (e.g., a tunable laser diode (TLD)). In addition, the heater 111 and the heater combined temperature sensor unit 120 may be disposed adjacent to a phase shifter, an optical amplifier (e.g., a semiconductor optical amplifier (SOA)), and/or an antenna.

The heater combined temperature sensor unit 120 may include an analog-to-digital converter (ADC) 121, a memory 122, and a micro-controller 123. The heater combined temperature sensor unit 120 may include a digital-to-analog converter (DAC) 124 and a driver 125.

The ADC 121 may measure at least one of voltage or current of the heater 111. The ADC 121 may convert an analog signal including information about at least one of voltage or current of the heater 111 into a digital signal. The ADC 121 may transfer the information (hereinafter referred to as an ADC conversion value) about at least one of voltage or current of the heater 111 converted into the digital signal to the memory 122.

The memory 122 may acquire and store the ADC conversion value from the ADC 121. Also, the memory 122 may store a program command for calibration. The memory 122 may transfer at least one of the ADC conversion value or the program command to the micro-controller 123.

The memory 122 may include at least one of volatile storage medium or non-volatile storage medium. For example, the memory 122 may include at least one of read only memory (ROM) or random access memory (RAM). The memory 122 may include at least one of programmable ROM (PROM), erasable ROM (EPROM), electrically erasable programmable ROM (EEPROM), or flash memory.

The micro-controller 123 may read information (e.g., the ADC conversion value) stored in the memory 122. The micro-controller 123 may obtain a correlation between the temperature and the ADC conversion value using the ADC conversion value. To this end, the micro-controller 123 may obtain temperature information from an external thermometer. The micro-controller 123 may store the correlation between the temperature and the ADC conversion value in the memory 122. In addition, the micro-controller 123 may calculate a temperature corresponding to a specific ADC conversion value by using the stored correlation between the temperature and the ADC conversion value.

The micro-controller 123 may include a central processing unit (CPU), an application processor (AP), or a dedicated processor by which methods according to embodiments of the present application are performed.

The DAC 124 may convert an adjustment signal according to the temperature calculated by the micro-controller 123 into an analog signal, and the output voltage of the DAC 124 may be applied to the driver 125.

The driver 125 may receive the voltage from the DAC 124 to drive an optical device. The driver 125 may receive the voltage from the DAC 124 and provide current to the heater 111. A temperature monitoring signal (111→121→122→123) using the heater 1110 and a driving signal (123→124→125→111) may not interfere with each other. Therefore, even while driving the heater 1110, the value of the driving signal may be effectively calibrated by using the resistance change according to the temperature change of the doped silicon.

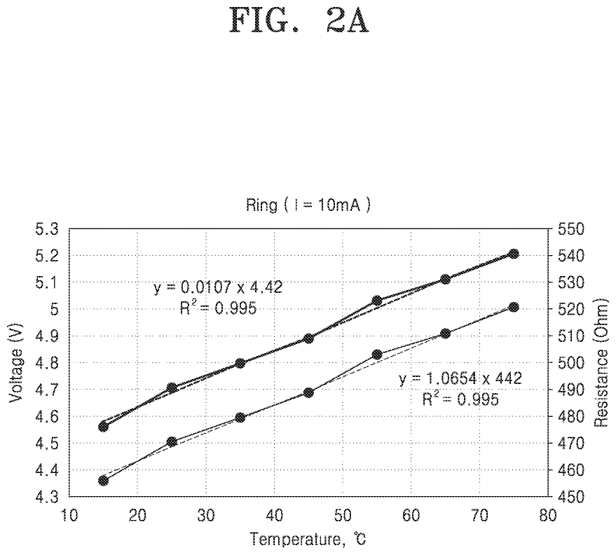

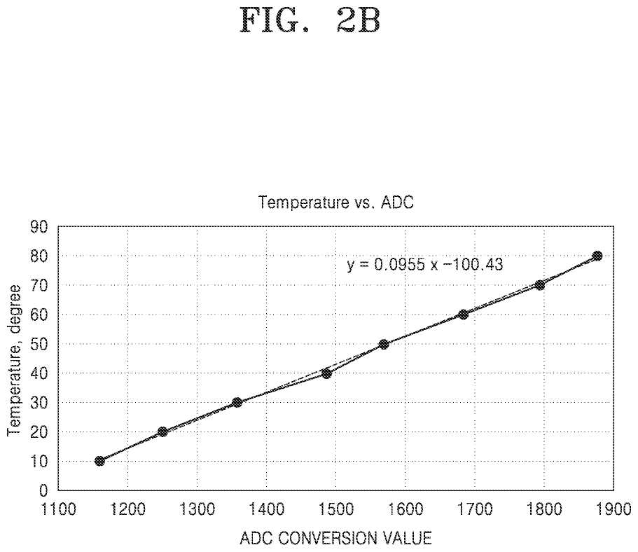

FIG. 2A is a graph showing a correlation between resistance and voltage of the heater 111 and temperature, and FIG. 2B is a graph of an ADC fitting function showing a correlation between an ADC conversion value and temperature. Here, it may be assumed that when the effective doping concentration of the heater 111 is 1e²⁰ cm⁻³ to 4e¹⁹ cm⁻³, the specific resistance is 8e⁻⁴ cmΩ to 1.6e⁻³ cmΩ, at room temperature, and a fixed current of 10 mA flows through a ring resonator. In FIGS. 2A and 2B, solid lines represent correlations between resistance and temperature of the heater 111, and dashed lines in FIG. 2A represent correlations between voltage and temperature of the heater 111.

Referring to the solid line in FIG. 2A, the resistance (right y-axis, Ohms) of the heater 111 may proportionally increase as the temperature (x-axis, ° C.) rises. For example, when the resistance to temperature of the heater 111 is measured, a regression equation of the resistance to temperature of the heater 111 may be expressed as y=1.0654x+422, and a coefficient of determination R² may be 0.995. Also, referring to the dashed line in FIG. 2A, the voltage (left y-axis, V) of the heater 111 may proportionally increase as the temperature (x-axis, ° C.) rises. For example, when the voltage with respect to the temperature of the heater 111 is measured, a regression equation of the voltage to temperature of the heater 111 may be expressed as y=0.0107x+4.22, and the coefficient of determination R² may be 0.995. Referring to the solid line in FIG. 2B, the temperature of the heater 111 may proportionally rise as the ADC conversion value increases. A regression equation of the temperature (y-axis, ° C.) to the ADC conversion value (x-axis) of the heater 111 may be expressed as y=0.0955x−100.43.

Therefore, the micro-controller 123 may calculate a slope value a and an offset value b of a linear function y=ax+b representing the relationship between the ADC conversion value and the temperature using the temperature (x-axis, ° C.) and information of the ADC conversion value (y-axis) at the temperature. In this case, the relation information between the temperature and the ADC conversion value may include the slope value a and the offset value b of the linear function y=ax+b described above. The micro-controller 123 may transfer the slope value a and the offset value b of the linear function y=ax+b described above to the memory 122.

In addition, the micro-controller 123 may acquire the relation information between the temperature and the ADC conversion value from the memory 122. The micro-controller 123 may calculate the temperature using the ADC filling function that shows the relation between the temperature and the ADC conversion value. As such, the micro-controller 123 may calibrate temperature values measured from the heater 11 using the ADC filling function. As a result, it may not be necessary to perform a performance measurement of an optical device, which includes the heater combined temperature sensor 100. For example, according to embodiments of the present disclosure, it may not be necessary to use an on-chip monitoring device to measure the laser output power of the optical device at different temperatures for temperature calibration purposes.

For example, as described above, when the relation information between the temperature and the ADC conversion value includes the slope value a and the offset value b of the linear function y=ax+b described above, the micro-controller 123 may calculate a temperature x corresponding to an ADC conversion value y at the temperature to be calculated using the slope value a and the offset value b as shown in Equation 1 below.

$$x = \frac{y - b}{a} \qquad [ Equation 1 ]$$

The calculated temperature may be used as important information to calibrate temperature dependent performance of silicon photonics devices. When a change in the performance of each device according to the temperature characteristics is known in advance, the change in the performance may be calibrated by utilizing a feedback control loop according to the temperature change. For example, the micro-controller 123 may adjust the voltage in a constant current mode using, for example, the calculated temperature of the doped heater 111 to calibrate the performance.

The heater combined temperature sensor 100 may serve as both a heater and a temperature sensor, and thus, an additional external device for temperature measurement may not be required except when the relation information between the temperature and the ADC conversion value is initially obtained. In addition, even when a monitoring device is required due to a problem in calibration accuracy, temperature calibration may be quickly optimized by estimating an optimal initialization value at a specific temperature.

The heater combined temperature sensor 100 may be applied to at least one of an optical amplifier, a phase shifter, or an antenna on an optical phased array (OPA) chip as well as the TLD. Hereinafter, embodiments to which the disclosure may be applied are described in detail.

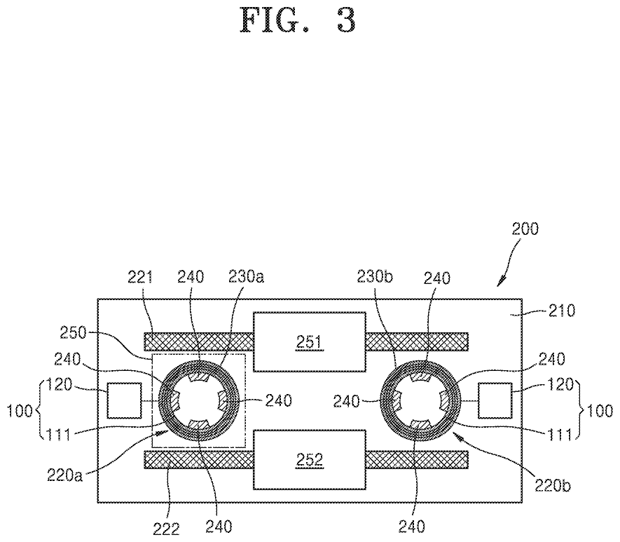

FIG. 3 is a schematic diagram of a tunable laser diode (TLD) 200 including the heater combined temperature sensor 100 according to an embodiment.

Referring to FIG. 3, the TLD 200 may include the heater combined temperature sensor 100. The TLD 200 may include a first waveguide 221 and a second waveguide 222. The first waveguide 221 and the second waveguide 222 may be disposed parallel to each other.

A first optical amplifier 251 may be provided on the first waveguide 221. A second optical amplifier 252 may be provided on the second waveguide 222. Each of the first optical amplifier 251 and the second optical amplifier 252 may be, for example, a silicon optical amplifier (SOA) or an ion-doped amplifier. Each of the first optical amplifier 251 and the second optical amplifier 252 may also serve as a light source. A first ring resonator 230a and a second ring resonator 230b may be disposed between the first waveguide 221 and the second waveguide 222. Each of the first ring resonator 230a and the second ring resonator 230b may include a ring waveguide, and the heater 111 of a ring shape may be disposed along the ring waveguide in an inner circumference of each of the first ring resonator 230a and the second ring resonator 230b. A plurality of electrodes 240 may be disposed on the inner circumference of the heater 111. A ring structure 250 may include the heater 111, the first ring resonator 230a, and the plurality of electrodes 240.

The first optical amplifier 251 may amplify a light beam input to the first waveguide 221 and may transmit the amplified light beam to the first ring resonator 230a. The transmitted light beam may be input to the second waveguide 222 after circulating through the first ring resonator 230a. The second optical amplifier 252 may amplify the light beam input to the second waveguide 222 and then may transmit the amplified light beam to the second ring resonator 230b and then to the first waveguide 221 again. In this process, the wavelength of light passing through a ring resonator may be adjusted by the heat generated by the heater 111. When light having a desired wavelength is generated by repeating the above process, the light may be emitted to the outside through the first waveguide 221 or the second waveguide 222. The light source shown in FIG. 3 is only an example, and light sources of various structures may be used.

As a substrate 210, for example, a silicon substrate may be used. However, this is only an example, and the substrate 210 may include other materials. A thermal conductor may be provided between the substrate 210 and the TLD 200. The thermal conductor may include at least one of thermal grease, sheet metal, or ceramic.

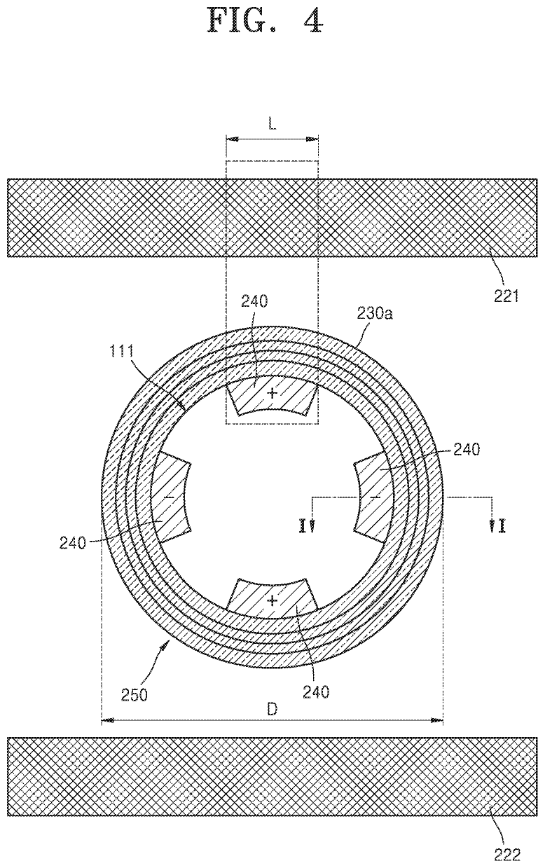

FIG. 4 is a diagram schematically illustrating the ring structure 250 of FIG. 3.

Referring to FIG. 4, the ring structure 250 may include the heater 111, the first ring resonator 230a, and the plurality of electrodes 240. The diameter D of the first ring resonator 230a may be 50 to 100 and a section L coupled with the first waveguide 221 or the second waveguide 222 may be 10 to 30 μm. The heater 111 may include doped silicon. The heater 111 may have a resistance R. The plurality of electrodes 240 may be disposed on the inner circumference of the heater 111. Current may flow through the heater 111 by current applied to the electrodes 240.

For example, as shown in FIG. 4, (+) electrodes may be disposed at 12 o'clock and 6 o'clock positions on the upper surface of the heater 111 of a ring shape, and (−) electrodes may be disposed at 3 o'clock and 9 o'clock positions on the upper surface of the heater 111.

A heater combined temperature sensor unit may be disposed adjacent to the heater 111.

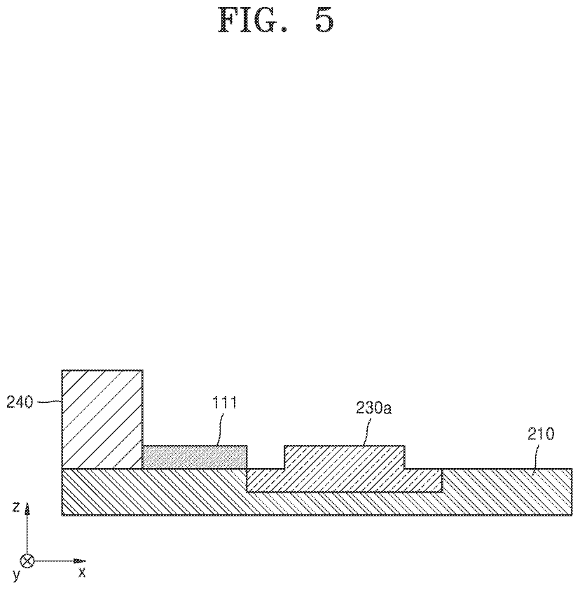

FIG. 5 is a cross-sectional view of the ring structure of FIG. 4 taken along a line I-I.

Referring to FIG. 5, the first ring resonator 230a may be disposed on the substrate 210. The first ring resonator 230a may include a lower end portion having a certain width on the x-axis and an upper protrusion portion positioned at the center of the upper surface of the lower end portion. The width of the upper protrusion portion of the first ring resonator 230a on the x-axis may be greater than the width of the lower end portion on the x-axis. The heater 111 may be circularly disposed on the inner circumference of the first ring resonator 230a. The heater 111 may include silicon doped with impurities. A level of one side surface of the heater 111 on the x-axis may coincide with a level of one side surface of the first ring resonator 230a on the x-axis. The heater 111 may have a certain width on the x-axis. The other side surface of the heater 111 may contact one side surface of the electrode 240. The heater 111 may have a certain length along the inner circumference of the first ring resonator 230a on the y-axis. A level of the lower end portion of the heater 111 on the z-axis may coincide with a level of the upper surface of the lower end portion of the first ring resonator 230a on the x-axis. The level of the lower end portion of the heater 111 on the z-axis may coincide with a level of the electrode 240 on the z-axis.

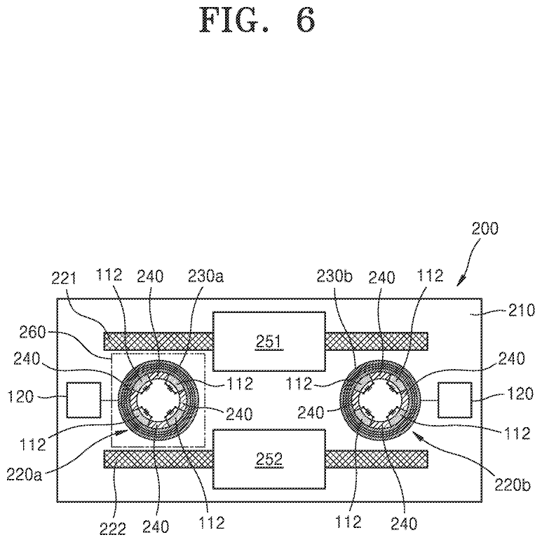

FIG. 6 is a diagram schematically illustrating the TLD 200 including a heater combined temperature sensor according to another embodiment.

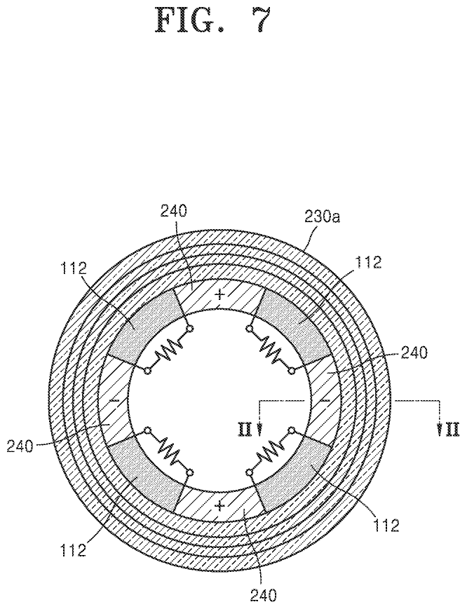

FIG. 7 is a diagram schematically illustrating a ring structure of FIG. 6.

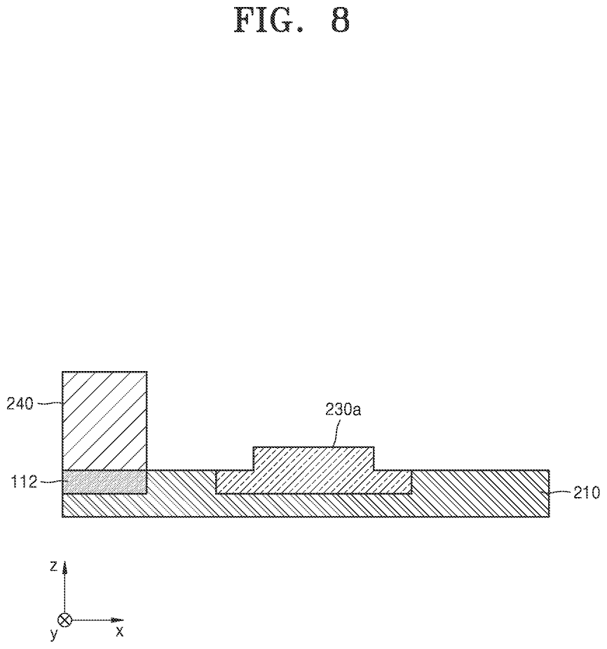

FIG. 8 is a cross-sectional view of the ring structure of FIG. 7 taken along a line II-II.

Referring to FIG. 6, when compared to FIGS. 3 to 5, a heater 112 may be spaced apart from the inner circumference of the first ring resonator 230a by a certain distance and doped on the substrate 210. In addition, the plurality of electrodes 240 may be disposed on the heater 112. Referring to FIG. 7, when four electrodes 240 are disposed on the upper surface of the heater 112 of a ring shape as shown in FIG. 4, the heater 112 may have a parallel resistance R/4. Referring to FIG. 8, the heater 112 may be circularly spaced apart from the first ring resonator 230a by a certain distance from the inner circumference of the first ring resonator 230a and doped on the substrate 210. For example, the heater 112 may be spaced apart from an upper protrusion portion of the first ring resonator 230a by a width on the x-axis and doped on the substrate 210. The heater 112 may be doped on the substrate 210 by a certain width on the x-axis. The heater 112 may be doped on the substrate 210 along the inner circumference of the first ring resonator 230a by a certain length on the y-axis. The heater 112 may be doped on the substrate 210 by a certain depth on the z-axis. A level of the upper surface of the heater 112 on the z-axis may coincide with a level of the upper surface of the substrate 210 on the z-axis.

For example, the doped width of the heater 112 may be equal to or greater than 1 μm and equal to or less than 3 μm, and the doped depth thereof may be equal to or greater than 100 nm and equal to or less than 200 nm. The heater 112 may be doped with impurities at a high concentration. For example, the heater 112 may be doped with impurities at a concentration equal to or greater than 4.5 s 10¹⁹ cm⁻³ and equal to or less than 1.0 s 10²⁰ cm⁻³. The heater 112 may include at least one of a p-type doped region or an n-type doped region.

A heater combined temperature sensor unit may be disposed adjacent to the heater 112.

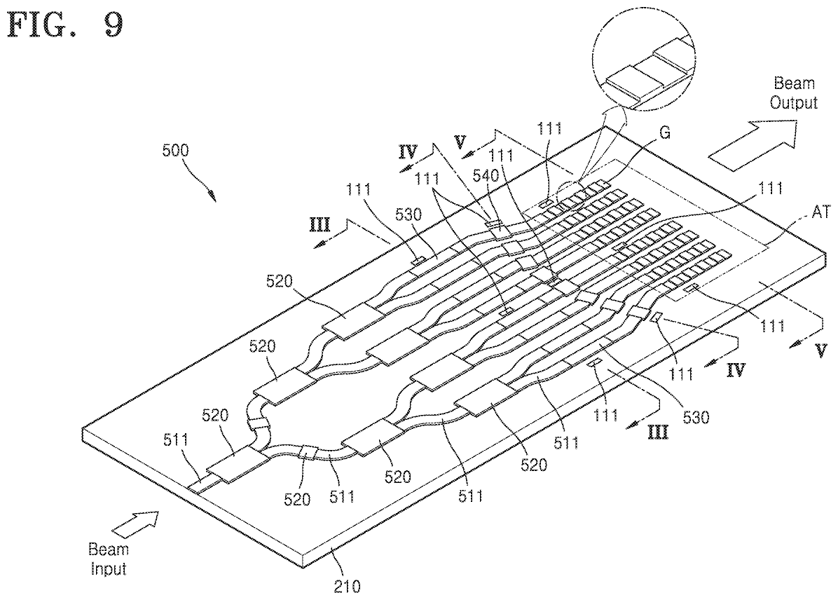

FIG. 9 is a schematic diagram of an optical phased array (OPA) 500 including a heater combined temperature sensor according to an embodiment.

Referring to FIG. 9, the OPA 500 may include a waveguide 511 transmitting a beam radiated from at least one light source, beam splitters 520 splitting light beams transmitted through the waveguide 511, phase shifters 530 shifting phases of the light beams, at least one optical amplifier 540 amplifying the light beams transmitted through the waveguide 511, and an antenna AT steering and radiating the light beams transmitted through the waveguide 511.

The waveguide 511 through which light travels may split into a plurality of waveguides 521 by the beam splitters 520. In FIG. 9, external light is incident onto one waveguide 511 which is split into eight waveguides 511 by seven beam splitters 520. The phase shifters 530 may be provided to the waveguides 511 split by the beam splitters 520. The phase shifters 530 may independently change phases of light beams passing through the waveguide 511 as electrical signals are applied. The at least one optical amplifier 540 may be further provided to the waveguide 511. The optical amplifier 540 may include a SOA or an ion-doped amplifier. The antenna AT may be further provided at an end of the waveguide 511 extending from the optical amplifier 540. The antenna AT may include a grating G formed on the waveguide 511. The traveling direction of the light beam may be adjusted according to the size, depth, pitch, etc. of the grating G. As shown in FIG. 5, the heaters 111 may be disposed close to the phase shifters 530, the optical amplifier 540, and the antenna AT. The heaters 111 may be spaced apart from each other by a certain distance in the waveguide 511 passing through at least one of the beam splitter 520, the phase shifter 530, the optical amplifier 540, or the antenna AT. A heater combined temperature sensor unit may be disposed close to the heaters 111. The heater combined temperature sensor unit may be electrically connected to the one or more heaters 111. The heaters 111 of FIG. 9 may be replaced with the heaters 112 according to another embodiment.

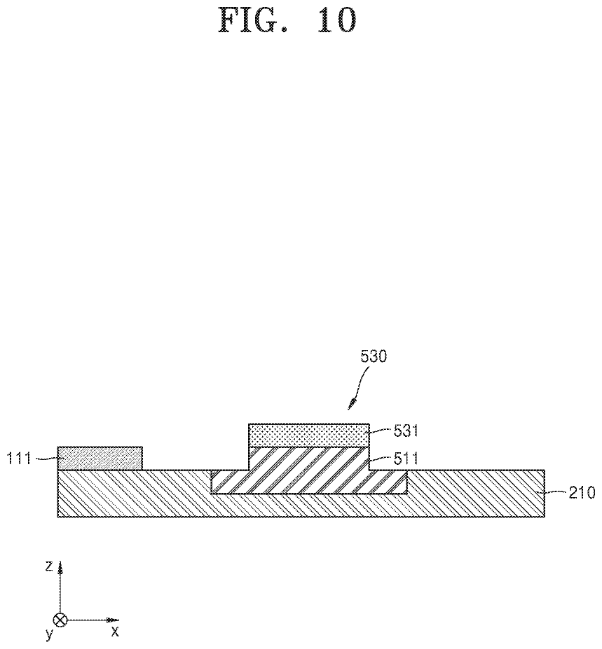

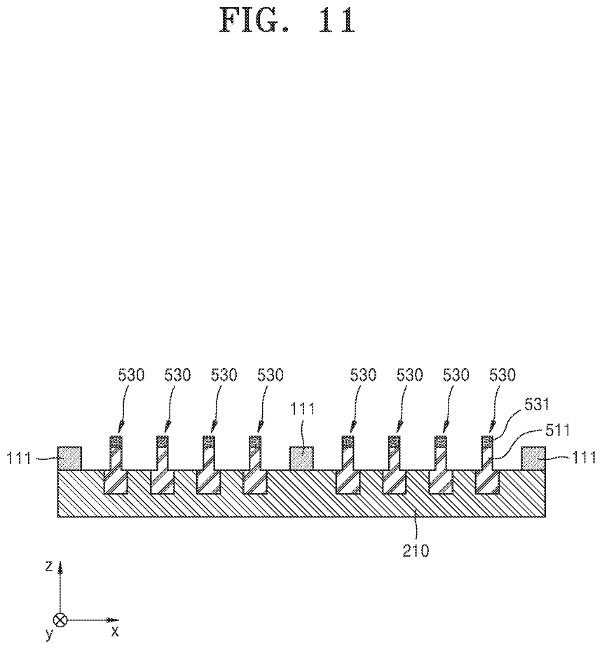

FIGS. 10 to 11 are cross-sectional views taken along a line III-Ill of FIG. 9 according to an embodiment.

Referring to FIG. 10, each of the phase shifters 530 may include the waveguide 511 provided on the substrate 210, a cladding layer 531 provided on the upper surface of the waveguide 511, and the heater 111 provided close to the waveguide 511.

The cladding layer 531 is provided on the upper surface of the waveguide 511. The cladding layer 531 may modulate a phase of a light beam passing through the waveguide 511.

In the phase shifter 530, when an electrical signal such as a voltage is applied to the cladding layer 531 through a driving unit, the carrier density may change inside the cladding layer 531 at the interface between the cladding layer 531 and the waveguide 511, and the refractive index of the cladding layer 531 may change according to a change in the carrier density. When the refractive index of the cladding layer 531 changes, the phase of a light beam passing through the waveguide 511 below the cladding layer 531 may be modulated due to evanescent wave interference.

Referring to the OPA 500 including the phase shifter 530 as shown in FIG. 9, a light beam may be incident on one waveguide 511 and then emitted through the plurality of waveguides 511 split by the beam splitters 520, and radiated to a specific position by the interference of a bundle of the emitted light beams. Here, phases of the light beams passing through the waveguides 511 may be modulated by the phase shifter 530 and emitted, and thus, the phase profile of the finally emitted bundle of the light beams may be determined. In addition, the light beam may be radiated to a desired position by determining the traveling direction of the light according to the phase profile. The phase shifter 530 may perform scanning by adjusting the traveling direction of the light beam. For example, the phase shifter 530 may scan the light beam in a direction horizontal to the substrate 210.

The heater 111 may be provided adjacent to the waveguide 511 passing through the phase shifter 530. The heater 111 may be spaced apart from the phase shifter 530 by a certain distance on the x-axis. The heater 111 may have a certain width on the x-axis. The heater 111 may have a certain length on the y-axis. The heater 111 may be disposed on the upper surface of the substrate 210 and have a certain height on the z-axis. A level of the lower surface of the heater 111 on the z-axis may coincide with a level of the upper surface of the substrate 210 on the z-axis.

Referring to FIG. 11, the heater 111 may be disposed adjacent to the plurality of phase shifters 530 on the substrate 210. The heater 111 and the plurality of phase shifters 530 may be repeatedly disposed at a certain period. For example, a heater 111, four phase shifters 530, a heater 111, four phase shifters 530, and a heater 111 may be arranged sequentially on the x-axis.

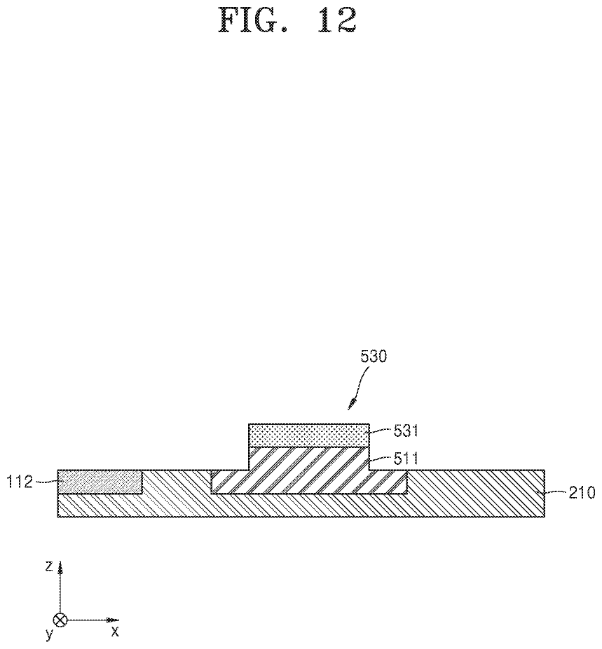

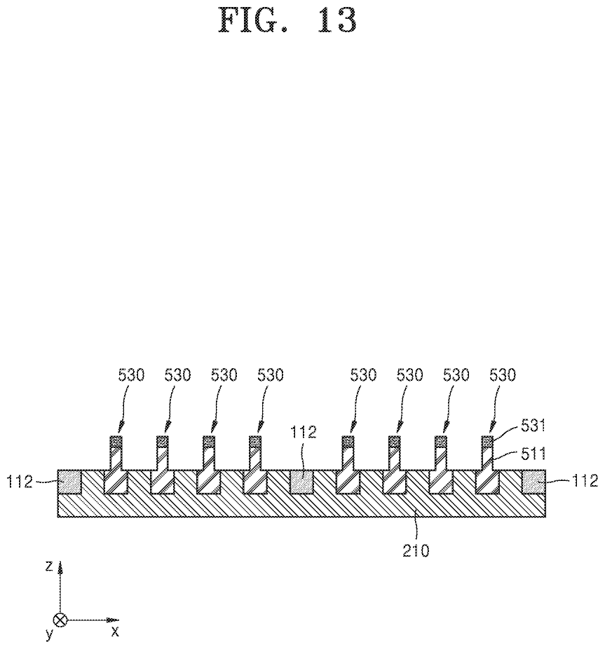

FIGS. 12 to 13 are cross-sectional views taken along the line III-Ill of FIG. 9 according to another embodiment.

Referring to FIG. 12, compared to FIGS. 10 to 11, the heater 112 may be doped on the substrate 210 by a certain depth on the z-axis. A level of the upper surface of the heater 112 on the z-axis may coincide with the level of the upper surface of the substrate 210 on the z-axis. The heater 112 may be doped on the substrate 210 by a certain width on the x-axis. The heater 112 may be doped on the substrate 210 by a certain length on the y-axis.

Referring to FIG. 13, similar to FIG. 11, the heater 112 may be disposed adjacent to the plurality of phase shifters 530 on the substrate 210. The heater 112 and the plurality of phase shifters 530 may be repeatedly disposed at a certain period. For example, a heater 112, four phase shifters 530, a heater 112, four phase shifters 530, and a heater 112 may be sequentially arranged on the x-axis.

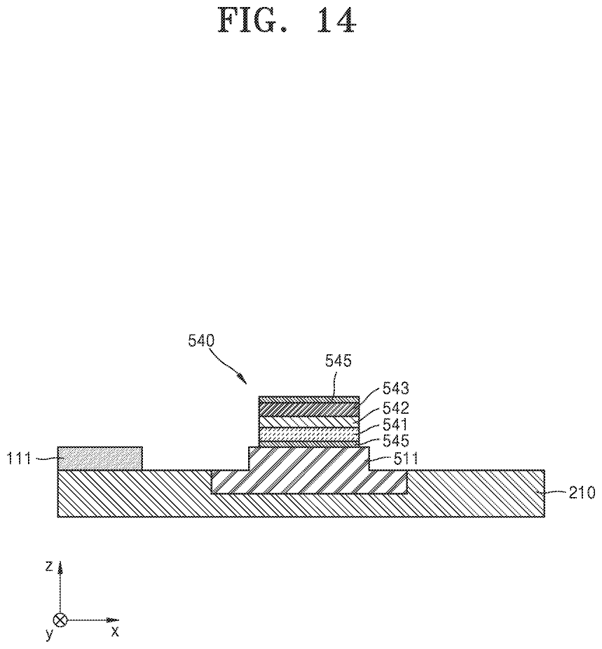

FIG. 14 is a cross-sectional view taken along a line IV-IV in FIG. 9 according to an embodiment.

Referring to FIG. 14, an optical amplifier 540 may include, for example, a lower cladding layer 541, an active layer 542, and an upper cladding layer 543. The lower cladding layer 541, the active layer 542, and the upper cladding layer 543 may include a Group III-V compound semiconductor material or a Group II-VI compound semiconductor material. The active layer 542 may include, for example, InGaAs, InGaNAs, InGaAsP, or InAlGaAs. Each of the lower cladding layer 541 and the upper cladding layer 543 may include a semiconductor material having a band gap that is greater than that of the active layer 542. Each of the lower cladding layer 541 and the upper cladding layer 543 may include, for example, GaAs, GaP, AlGaAs, InGaP, GaAs, or InP. The material of the optical amplifier 540 may be selected according to a wavelength (an energy bandgap) of light to be amplified. For example, when light having a wavelength of 1.55 μm is amplified, InP/InGaAs materials may be used for a cladding layer and an active layer.

A conductive layer 545 may be provided on each of the lower cladding layer 541 and the upper cladding layer 543. The conductive layer 545 may include a conductive material. Alternatively, the conductive layer 545 may include, for example, at least one of Ti, Au, Ag, Pt, Cu, Al, Ni, or Cr, an alloy, or a stack thereof. However, the conductive layer 545 is not limited thereto, and may include at least one of, for example, Indium-Tin-Oxide (ITO), Indium-Zinc-Oxide (IZO), Ga—In—Zn-Oxide (GIZO), Al—Zn-Oxide (AZO), Ga—Zn-Oxide (GZO), or ZnO. The conductive layer 545 itself is an electrode or a structure in which a separate electrode is coupled to the conductive layer 545 from the outside is also possible.

The heater 111 may be provided adjacent to the waveguide 511 passing through the optical amplifier 540. The heater 111 may be spaced apart from the optical amplifier 540 by a certain distance on the x-axis. The heater 111 may have a certain width on the x-axis. The heater 111 may have a certain length on the y-axis. The heater 111 may be disposed on the upper surface of the substrate 210 and have a certain height on the z-axis. A level of the lower surface of the heater 111 on the z-axis may coincide with a level of the upper surface of the substrate 210 on the z-axis. Similar to that shown in FIG. 11, the heater 111 and the plurality of optical amplifiers 540 may be repeatedly arranged at a certain period.

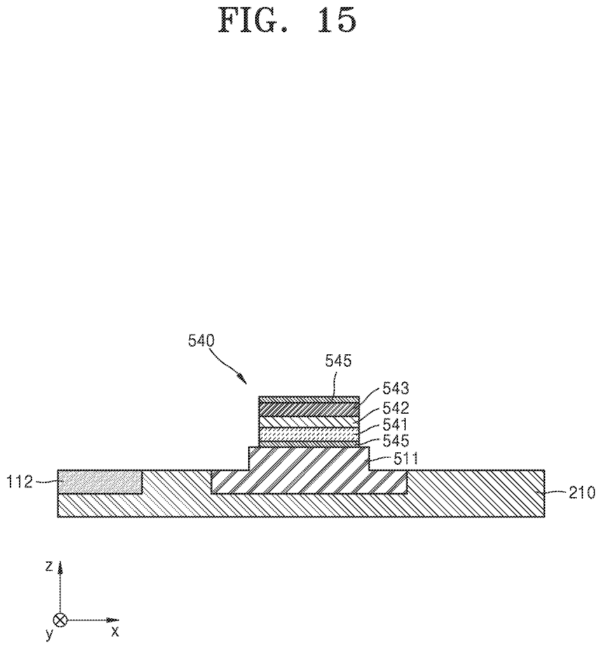

FIG. 15 is a cross-sectional view taken along the line IV-IV of FIG. 9 according to another embodiment.

Referring to FIG. 15, compared to FIG. 14, the heater 112 may be doped on the substrate 210 by a certain depth on the z-axis. A level of the upper surface of the heater 112 on the z-axis may coincide with a level of the upper surface of the substrate 210 on the z-axis. The heater 112 may be doped on the substrate 210 by a certain width on the x-axis. The heater 112 may be doped on the substrate 210 by a certain length on the y-axis. Similar to that shown in FIG. 12, the heater 112 and the plurality of optical amplifiers 540 may be repeatedly arranged at a certain period.

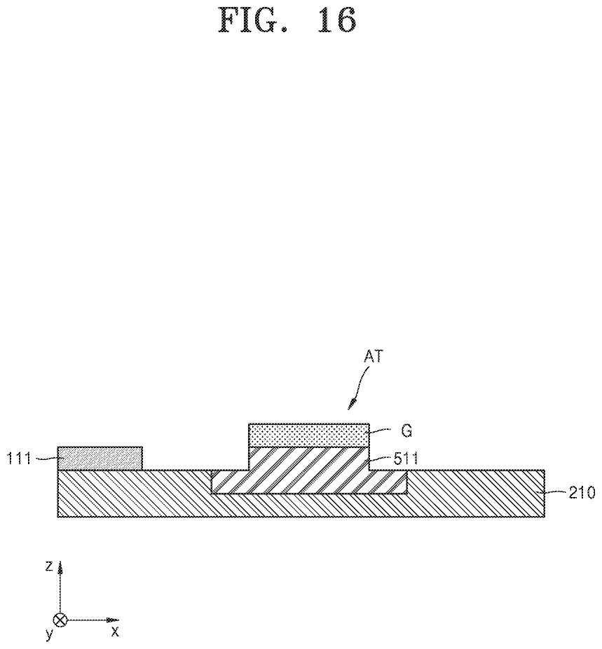

FIG. 16 is a cross-sectional view taken along a line V-V in FIG. 9 according to an embodiment.

Referring to FIG. 16, the heater 111 may be provided close to the waveguide 511 passing through the antenna AT. The heater 111 may be spaced apart from the waveguide 511 by a certain distance on the x-axis. The heater 111 may have a certain width on the x-axis. The heater 111 may have a certain length on the y-axis. The heater 111 may be disposed on the upper surface of the substrate 210 and have a certain height on the z-axis. A level of the lower surface of the heater 111 on the z-axis may coincide with a level of the upper surface of the substrate 210 on the z-axis. Similar to that shown in FIG. 11, the waveguides 511 passing through the heater 111 and the antenna AT may be repeatedly arranged at a certain period.

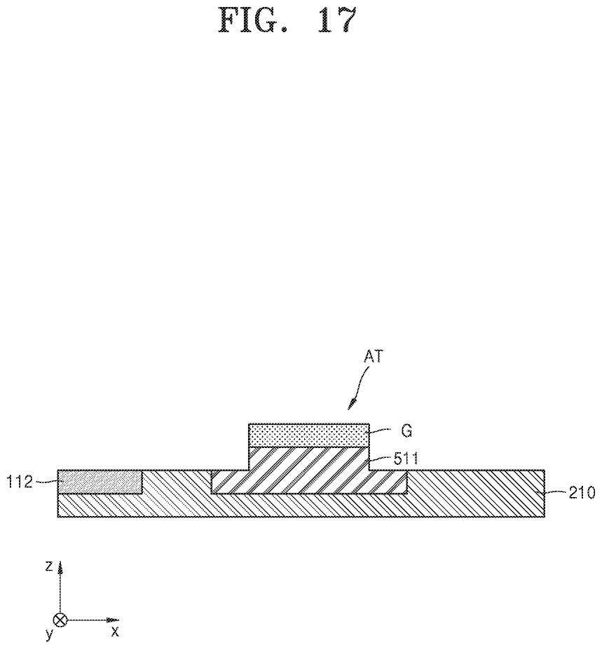

FIG. 17 is a cross-sectional view taken along the line V-V in FIG. 9 according to another embodiment.

Referring to FIG. 17, compared to FIG. 16, the heater 112 may be doped on the substrate 210 by a certain depth on the z-axis. A level of the upper surface of the heater 112 on the z-axis may coincide with a level of the upper surface of the substrate 210 on the z-axis. The heater 112 may be doped on the substrate 210 by a certain width on the x-axis. The heater 112 may be doped on the substrate 210 by a certain length on the y-axis. Similar to that shown in FIG. 12, the waveguides 511 passing through the heater 112 and the antenna AT may be repeatedly arranged at a certain period.

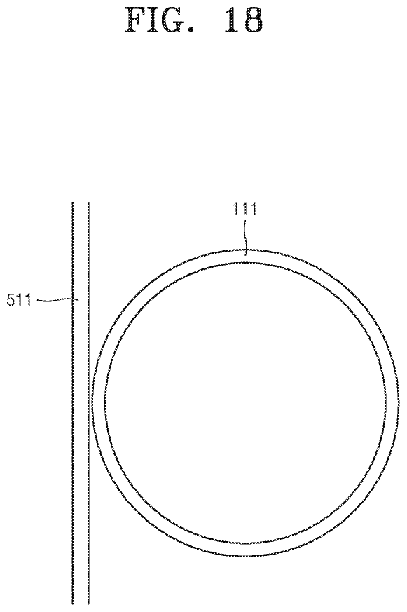

FIGS. 18 to 20 are diagrams schematically illustrating the waveguide 511 and the heater 111 according to another embodiment.

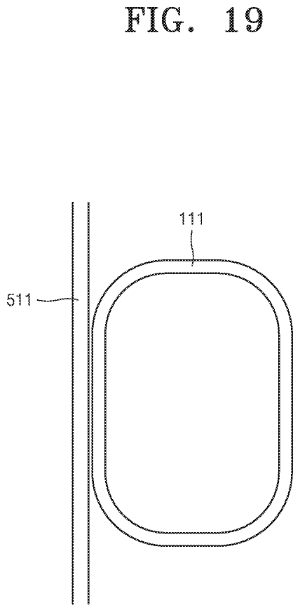

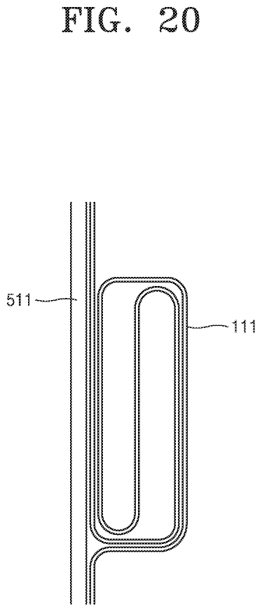

Referring to FIGS. 18 to 20, the heater 111 may be disposed in close to the waveguide 511. The heater 111 may have various shapes. For example, referring to FIG. 18, the heater 111 may have a ring shape. Referring to FIG. 19, the heater 111 may have a race track shape. Referring to FIG. 20, the heater 111 may have an S-band shape. In FIGS. 18 to 20, the heater 111 may be replaced with the heater 112 according to another embodiment.

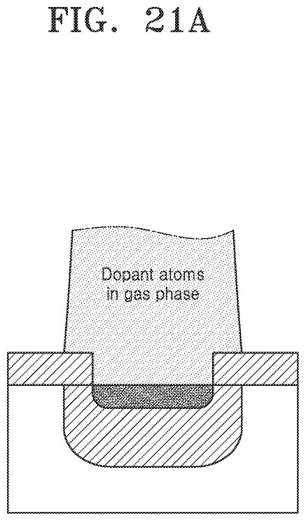

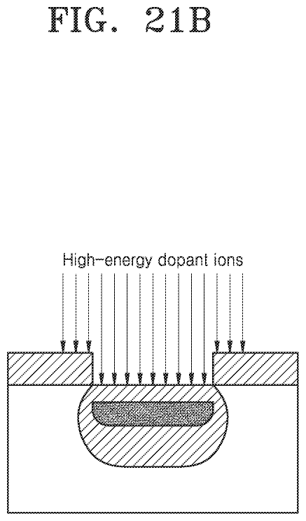

FIGS. 21A and 21B are diagrams schematically illustrating a doping process of a heater according to an embodiment. The heater may include silicon disposed on a substrate and may be doped according to the doping process described below. Alternatively, the heater may be formed by being doped on a substrate including silicon according to the doping process described below.

Referring to FIG. 21A, the heater may be doped using a high-temperature diffusion method. Alternatively, referring to FIG. 12B, the heater may be doped using an ion injection method using an ion beam.

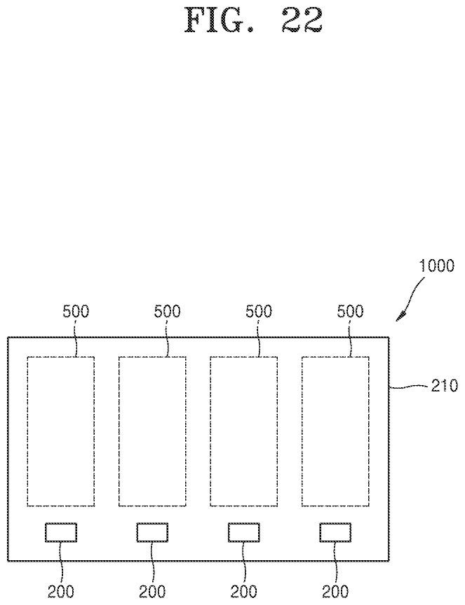

FIG. 22 is a block diagram schematically illustrating a beam steering apparatus 1000 according to an embodiment.

Referring to FIG. 22, the beam steering apparatus 1000 may include the substrate 210, one or more TLDs 200 provided on the substrate 210, and one or more OPAs 500 arranged on the same plane of the substrate 210.

The substrate 210 may be, for example, a silicon substrate. However, the substrate 210 is not limited thereto. The one or more TLDs 200 may include, for example, a first TLD, a second TLD, a third TLD, and a fourth TLD. The first to fourth TLDs may be configured to emit light of a single wavelength or light of multiple wavelengths. The one or more OPAs 500 may include, for example, a first OPA, a second OPA, a third OPA, and a fourth OPA. The first OPA, the second OPA, the third OPA, and the fourth OPA may be arranged on the same plane of one substrate 210. The OPAs 500 may be manufactured on the substrate 210 through a semiconductor process. Here, the numbers of TLDs 200 and the OPAs 500 are each 4, but the number or arrangement structure thereof may be variously modified. The OPAs 500 may be configured to adjust an output direction of light beams emitted from one or more light sources.

In the beam steering apparatus 1000 according to the embodiment, in addition to the TLD 200, a light source, such as a laser diode (LD), a light emitting diode (LED), a super luminescent diode (SLD), etc., may be applied.

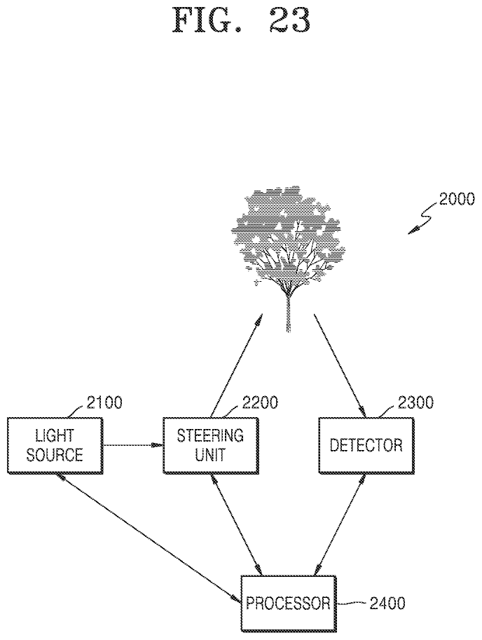

FIG. 23 is a block diagram illustrating a LiDAR device 2000 according to an embodiment.

As shown in FIG. 23, the LiDAR device 2000 may include a light source 2100 that generates light, a steering unit 2200 that steers light output from the light source 2100 toward an object, a detector 2300 that detects light reflected from the object, and a processor 2400 that performs an operation of obtaining information (e.g., depth information) about the object from the light detected by the detector 2300. The LiDAR device 2000 may further include a plurality of waveguides providing optical connections between the light source 2100 and the steering unit 2200 and between the steering unit 2200 and the detector 2300, respectively. The light source 2100, the steering unit 2200, the detector 2300, and the processor 2400 may be implemented as separate apparatuses or as one apparatus. For example, the light source 2100 and the steering unit 2200 may be implemented as the beam steering apparatus 1000 of FIG. 22.

The light source 2100 may be a TLD capable of adjusting the wavelength of emitted light. A plurality of laser beams may be emitted from the light source 2100, and laser beams having optical coherence among the plurality of laser beams may be incident into the steering unit 2200. The light source 2100 may generate and output light of a plurality of different wavelength bands. Also, the light source 2100 may generate and output pulsed light or continuous light.

The light source 2100 may include anal aster diode (LD), an edge emitting laser, a vertical-cavity surface emitting laser (VCSEL), a distributed feedback laser, an LED, a an SLD, etc.

The light source 2100 may be directly coupled (on-chip) or indirectly coupled (off-chip) to the waveguide. An on-chip light source may be implemented through III-V bonding or epitaxial growth. An off-chip light source may be implemented using vertical coupling, edge coupling, or chip alignment of an external light source.

The steering unit 2200 illuminates the object by changing the travel direction of light from the light source 2100, and may include an OPA device capable of adjusting the direction of light without mechanical movement. The OPA device may be the same as the OPA 500 of FIG. 9. The steering unit 2200 may transmit amplified light toward a forward local area in a one-dimensional (1D) or two-dimensional (2D) scanning method. To this end, the steering unit 2200 may sequentially or non-sequentially steer the light focused in a narrow area to forward 1D or 2D areas at a certain time interval. For example, the steering unit 2200 may be configured to emit a laser light from the bottom to the top or from the top to the bottom with respect to forward 1D areas. Also, the steering unit 2200 may be configured to emit a laser light from the left to the right or from the right to the left with respect to forward 1D areas.

The detector 2300 may detect the light reflected by the object and generate an electrical signal based on the detected light. The detector 2300 may include an array of light detection elements. The detector 2300 may further include a spectroscopic device analyzing the light reflected from the object for each wavelength.

The processor 2400 may perform an operation of obtaining information about the object from the light detected by the detector 2300. In addition, the processor 2400 may perform all the processing and control of the LiDAR device 2000. The processor 2400 may obtain and process the information about the object. For example, the processor 2400 may obtain and process 2D or 3D image information. The processor 2400 may generally control the driving of the light source 2100 and the steering unit 2200 or the operation of the detector 2300. For example, the processor 2400 may control an electrical signal applied to the OPA device included in the steering unit 2200. The processor 2400 may also analyze the distance between a target and the LiDAR device 2000, the shape of the target, etc. through numerical information provided by the detector 2300.

The 3D image obtained by the processor 2400 may be transmitted to and utilized by another unit. For example, such information may be transmitted to the processor 2400 of an autonomous driving device, such as a vehicle or a drone in which the LiDAR device 2000 is employed. In addition, such information may be utilized in a smartphone, a mobile phone, a personal digital assistant (PDA), a laptop, a personal computer (PC), a wearable device, and other mobile or non-mobile computing devices.

The LiDAR device 2000 according to embodiments may be applied to a smartphone, a mobile phone, a PDA, a laptop, a PC, or a wearable device. For example, the smartphone may extract depth information of subjects in an image, adjust out-of-focusing of the image, or automatically identify subjects in the image by using the LI DAR device 2000.

In addition, the LiDAR device 2000 according to embodiments may be applied to a vehicle. The vehicle may include a plurality of LiDAR devices 2000 disposed in various locations. The vehicle may provide various pieces of information about the inside or surroundings of the vehicle to a driver, and automatically recognize objects or persons in the image to provide information necessary for autonomous driving, by using the LI DAR device 2000.

Applications implemented in silicon photonics integrated circuits according to the present embodiment may maintain a certain temperature range by using a heater combined temperature sensor and may satisfy performance requirements. Thus, a lasing spectrum, power and peak wavelength stability of a system may be greatly improved.

A heater and a heater combined temperature sensor unit according to various embodiments may be applied to the LiDAR device 2000. The LiDAR device 2000 may radiate a laser to a target and detect the distance, direction, speed, temperature, material distribution and concentration characteristics to the object. LiDAR may be used in a laser scanner and a 3D imaging camera for autonomous driving cars.

LiDAR for vehicles, LiDAR for robots, LiDAR for drones, etc. may be applied to the LiDAR device 2000. In addition, the beam steering apparatus according to various embodiments may be applied to a security intruder detection system, a subway screen door obstacle detection system, a depth sensor, a user face recognition sensor in a mobile phone, motion recognition and object profiling in augmented reality (AR), a TV or an entertainment device, etc.

According to embodiments, an optical device and a LiDAR device each including a heater combined temperature sensor may infer a temperature change using a change in at least one of voltage or current of a thermistor according to temperature. In addition, an optical device and a LiDAR device each including a heater combined temperature sensor may calibrate the performance change in a silicon photonics optical integrated circuit according to the temperature. Accordingly, lasing spectrum, power, and peak wavelength stability may be greatly improved.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An optical device comprising:
a substrate;
a waveguide disposed on the substrate;
a heater configured as a silicon region doped on a part of the substrate;
an analog-to-digital converter (ADC) configured to measure a voltage of the heater and convert the voltage of the heater into an ADC conversion value;
a memory storing relation information between temperature and the ADC conversion value; and
a micro-controller configured to estimate a temperature of the heater using the relation information between the temperature and the ADC conversion value.

2. The optical device of claim 1, wherein a doped width of the heater is equal to or greater than 1 μm and equal to or less than 3 μm, and a doped depth of the heater is equal to or greater than 100 nm and equal to or less than 200 nm.

3. The optical device of claim 1, wherein a doping concentration of the heater is equal to or greater than 4.5 s 10¹⁹ cm⁻³ and equal to or less than 1.0 s 10²⁰ cm⁻³.

4. The optical device of claim 1, wherein the heater has one of a ring shape, a straight line shape, a race track shape, and an S-band shape.

5. The optical device of claim 1, further comprising:
a digital-to-analog converter (DAC) configured to convert an adjustment signal according to the temperature calculated by the micro-controller into an adjustment voltage; and
a driver configured to receive the adjustment voltage and supply current.

6. The optical device of claim 1, wherein the micro-controller is configured to calculate a relationship between the temperature and the ADC conversion value using temperature information obtained from a thermometer and the ADC conversion value.

7. A light detection and ranging (LiDAR) device comprising:
a tunable laser diode;
a phase shifter;
an optical amplifier;
an antenna;
a heater configured as a doped silicon region; and
a heater combined temperature sensor.

8. The LiDAR device of claim 7, wherein the heater and the heater combined temperature sensor are disposed inside the tunable laser diode.

9. The LiDAR device of claim 7, wherein the heater and the heater combined temperature sensor are disposed adjacent to the phase shifter.

10. The LiDAR device of claim 7, wherein the heater and the heater combined temperature sensor are disposed adjacent to the optical amplifier.

11. The LiDAR device of claim 7, wherein the heater and the heater combined temperature sensor are disposed adjacent to the antenna.

12. The LiDAR device of claim 7, wherein a doped width of the heater is equal to or greater than 1 μm and equal to or less than 3 μm, and a doped depth of the heater is equal to or greater than 100 nm and equal to or less than 200 nm.

13. The LiDAR device of claim 7, wherein a doping concentration of the heater is equal to or greater than 4.5 s 10¹⁹ cm⁻³ and equal to or less than 1.0 s 10²⁰ cm⁻³.

14. The LiDAR device of claim 7, wherein the heater has one of a ring shape, a straight line shape, a race track shape, and an S-band shape.

15. The LiDAR device of claim 7, wherein the heater combined temperature sensor includes:
an analog-to-digital converter (ADC) configured to measure a voltage of the heater and convert the voltage of the heater into an ADC conversion value;
a memory storing relation information between temperature and the ADC conversion value; and
a micro-controller configured to estimate a temperature using the relation information between the temperature and the ADC conversion value.

16. The LiDAR device of claim 15, wherein the heater combined temperature sensor further includes:
a digital-to-analog converter (DAC) configured to convert an adjustment signal according to the temperature calculated by the micro-controller into an adjustment voltage; and
a driver configured to receive the adjustment voltage and supply current.

17. The LiDAR device of claim 15, wherein the micro-controller is configured to calculate a relationship between the temperature and the ADC conversion value using temperature information obtained from a thermometer and the ADC conversion value.

18. An optical device comprising:
a doped silicon thermistor configured to collect temperature sensing data;
a waveguide coupled with the doped silicon thermistor;
an analog digital converter (ADC) configured to convert an analog signal containing the temperature sensing data into a digital signal that represents a digital temperature value;
a memory storing an ADC fitting function that expresses a relation between ADC conversion values and temperatures; and
a processor configured to estimate a temperature of the doped silicon thermistor based on the digital temperature value and the ADC fitting function.

19. The optical device of claim 18, wherein the optical device is a light detection and ranging (LiDAR) sensor, and further comprises:
a tunable laser diode;
a phase shifter;
an optical amplifier; and
an antenna.
